(19) United States
(12) Patent Application Publication
(10) Pub. No.: US 2024/0191344 A1
(43) Pub. Date: Jun. 13, 2024

(54) SURFACE TREATMENT METHOD AND SUBSTRATE TREATMENT DEVICE

(71) Applicant: Tokyo Electron Limited, Minato-ku, Tokyo (JP)

(72) Inventors: Hiroki MURAKAMI, Nirasaki City, Yamanashi (JP); Shuji AZUMO, Nirasaki City, Yamanashi (JP); Yumiko KAWANO, Nirasaki City, Yamanashi (JP)

(21) Appl. No.: 18/555,055

(22) PCT Filed: Apr. 7, 2022
(86) PCT No.: PCT/JP2022/017252

§ 371 Date: Oct. 12, 2023

(30) Foreign Application Priority Data
Apr. 15, 2021 (JP) 2021-068978

(51) Int. Cl. C23C 16/18; C23C 16/02; C23C 16/34

(52) U.S. Cl. CPC C23C 16/18; C23C 16/0227; C23C 16/345

(57) ABSTRACT

A surface processing method of removing a metal oxide film on a surface of a metal layer and a substrate processing apparatus are provided. The surface processing method for a substrate having a metal layer includes supplying a metal complex compound having a cyclopentadienyl ligand to a processing chamber and removing a metal oxide film on the surface of the metal layer using the metal complex compound.

### TECHNICAL FIELD

The present disclosure relates to a surface processing method and a substrate processing apparatus.

### BACKGROUND

A substrate processing method of forming a ruthenium film on a metal layer has been known.

Patent Document 1 discloses an embedding method including a process of supplying a ruthenium-containing gas into a processing chamber and a process of embedding, using the ruthenium-containing gas, ruthenium from a bottom of a recess, which is formed in an insulating layer on a substrate having a metal layer on the bottom.

### PRIOR ART DOCUMENT

### [Patent Document]

Patent Document 1: Japanese Patent Laid-Open Publication No. 2020-43139

### SUMMARY

In one embodiment, in order to form a structure around a metal layer after forming the metal layer, processes such as oxide film formation, dry etching, and ashing are performed, and the metal layer is exposed to an oxidizing atmosphere, thereby forming a metal oxide film on a surface of the metal layer. In addition, after forming the metal layer, by exposing the metal layer to atmospheric atmosphere, the surface of the metal layer is naturally oxidized and a metal oxide film is formed on the surface of the metal layer. Therefore, there is a need for a method of reducing the metal oxide film on the metal layer.

In one aspect, the present disclosure provides a surface processing method and a substrate processing apparatus that remove a metal oxide film on a surface of a metal layer.

According to another aspect, there is provided a surface processing method for a substrate having a metal layer, the method including supplying a metal complex compound having a cyclopentadienyl ligand to a processing chamber and removing a metal oxide film on a surface of the metal layer using the metal complex compound.

According to the present disclosure, it is possible to provide a surface processing method and a substrate processing apparatus that remove a metal oxide film on a surface of a metal layer.

### BRIEF DESCRIPTION OF DRAWINGS

FIG. 1 is an example of a cross-sectional view of a substrate processing apparatus according to the present embodiment.

FIG. 2 is a flowchart illustrating an example of a surface processing method for a substrate W according to a first embodiment.

FIG. 3 is a cross-sectional schematic diagram illustrating an example of a structure of a substrate.

FIG. 4A is an example of a reaction model in which a metal oxide film is removed by using a metal complex compound.

FIG. 4B is an example of a reaction model in which a metal oxide film is removed by using a metal complex compound.

FIG. 4C is an example of a reaction model in which a metal oxide film is removed by using a metal complex compound.

FIG. 4D is an example of a reaction model in which a metal oxide film is removed by using a metal complex compound.

FIG. 5 is an example of a graph illustrating oxygen concentrations at an interface between a SiN film and a metal layer in the surface processing method of the first embodiment and surface processing methods of reference examples.

FIG. 6 is a flowchart illustrating an example of a surface processing method for a substrate W according to a second embodiment.

FIG. 7 is a flowchart illustrating an example of a surface processing method for a substrate W according to a third embodiment.

FIG. 8A is a cross-sectional schematic diagram illustrating an example of an upper structure of a substrate.

FIG. 8B is a cross-sectional schematic diagram illustrating an example of an upper structure of a substrate.

### DETAILED DESCRIPTION

Hereinafter, embodiments for carrying out the present disclosure will be described with reference to the drawings. In each drawing, the same reference numerals may be given to the same components, and redundant descriptions may be omitted.

### <Substrate Processing Apparatus 100>

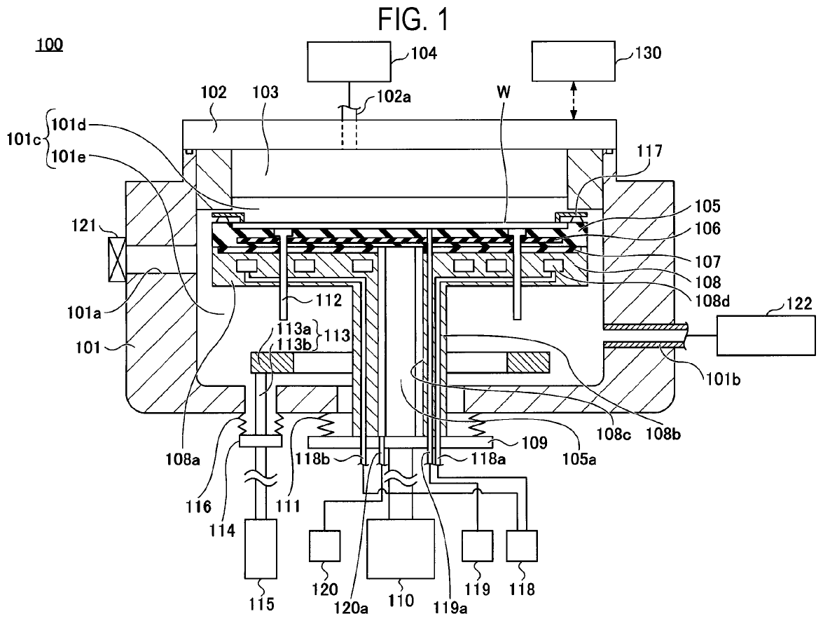

A substrate processing apparatus 100 according to the present embodiment will be described with reference to FIG. 1. FIG. 1 is an example of a cross-sectional view of the substrate processing apparatus 100 according to the present embodiment.

A main body container 101 is a bottomed container having an opening at a top. A support 102 supports a gas introduction mechanism 103. In addition, the support 102 closes the opening at the top of the main body container 101, so that the main body container 101 is sealed to form a processing chamber 101c. A gas supply 104 supplies a process gas to the gas introduction mechanism 103 via the support 102 having a supply pipe 102a. The process gas supplied from the gas supply 104 is supplied into the processing chamber 101c from the gas introduction mechanism 103.

In one embodiment, a stage 105 is a member that is formed in a flat disk shape using a material such as aluminum nitride or quartz, places a substrate W thereon. A heater 106 for heating the substrate W is embedded in the stage 105. The heater 106 is formed of, for example, a sheet-shaped resistance heating element, and generates heat upon receiving power supplied from a power supply (not illustrated) to heat a placement surface of the stage 105, thereby raising a temperature of the substrate W up to a predetermined process temperature. The heater 106 heats the substrate W placed on the stage 105 to a temperature within a range from 50 degrees C. to 500 degrees C., for example.

In addition, the stage 105 has a support portion 105a extending downward from a center of a lower surface of the stage 105. One end of the support portion 105a passes through the bottom of the main body container 101 and is supported by a lifting mechanism 110 via a lifting plate 109.

In addition, a temperature regulation jacket 108 as a temperature regulation member is provided below the stage 105. The temperature regulation jacket 108 has an upper plate portion 108a having substantially the same size as the stage 105 and a lower shaft portion 108b having a larger diameter than the support portion 105a. In addition, the temperature regulation jacket 108 is formed with a bore 108c, which centrally and vertically passes through the plate portion 108a and the shaft portion 108b.

The temperature regulation jacket 108 accommodates the support portion 105a in the bore 108c, and is disposed to cover an entire back surface of the stage 105 while covering the support portion 105a with the bore 108c. Since the bore 108c is a diameter larger than the diameter of the support portion 105a, a gap (not illustrated) is formed between the support portion 105a and the temperature regulation jacket 108.

The temperature regulation jacket 108 has a coolant flow path 108d formed inside the plate portion 108a, and is provided with two coolant pipes 118a and 118b inside the shaft portion 108b. The coolant flow path 108d has one end connected to one coolant pipe 118a and the other end connected to the other coolant pipe 118b. The coolant pipes 118a and 118b are connected to a coolant unit 118.

In one embodiment, the coolant unit 118 is a chiller unit. The coolant unit 118 is configured to control a temperature of a coolant, and supplies the coolant of a predetermined temperature to the coolant pipe 118a. The coolant is supplied to the coolant flow path 108d from the coolant unit 118 via the coolant pipe 118a. The coolant supplied to the coolant flow path 108d returns to the coolant unit 118 through the coolant pipe 118b. The temperature regulation jacket 108 is configured to perform temperature adjustment by circulating the coolant such as cooling water in the coolant flow path 108d.

A heat insulation ring 107 as a heat insulation member is disposed between the stage 105 and the temperature regulation jacket 108. The heat insulation ring 107 is formed in a disk shape using a material, for example, SUS316, A5052, titanium (Ti), or ceramic.

Between the heat insulation ring 107 and the stage 105, a gap that provides communication from the bore 108c to a rim of the temperature regulation jacket 108 is formed along an entire circumference. For example, the heat insulation ring 107 is provided with a plurality of protrusions on an upper surface thereof facing the stage 105.

The plurality of protrusions on the heat insulation ring 107 is formed in a plurality of, e.g., two, concentric circular rows at intervals in a circumferential direction. Alternatively, the protrusions may be formed in at least one concentric circular row.

The shaft portion 108b of the temperature regulation jacket 108 passes through the bottom of the main body container 101. A lower end of the temperature regulation jacket 108 is supported by the lifting mechanism 110 via the lifting plate 109 disposed below the main body container 101. A bellows 111 is provided between the bottom of the main body container 101 and the lifting plate 109 to maintain airtightness inside the main body container 101 even with a vertical movement of the lifting plate 109.

By moving the lifting plate 109 vertically by the lifting mechanism 110, the stage 105 can be moved vertically between a processing position (see FIG. 1) where the substrate W is processed and a transfer position (not illustrated) where the substrate W is transferred to and from an external transfer mechanism (not illustrated) via a loading/unloading port 101a.

When transferring the substrate W to and from the external transfer mechanism (not illustrated), lifting pins 112 support the substrate W from a lower surface thereof to raise the substrate W from the placement surface of the stage 105. Each lifting pin 112 has a shaft portion and a head portion with a larger diameter than the shaft portion. The stage 105 and the plate portion 108a of the temperature regulation jacket 108 are formed with through-holes through which the shaft portion of the lifting pin 112 is inserted. In addition, a groove for accommodating the head portion of the lifting pin 112 is formed on the placement surface side of the stage 105. An abutter 113 is disposed below the lifting pin 112.

In a state where the stage 105 is moved to the processing position of the substrate W (see FIG. 1), the head portion of the lifting pin 112 is accommodated in the groove, and the substrate W is placed on the placement surface of the stage 105. In addition, the head portion of the lifting pin 112 is engaged and locked in the groove, and the shaft portion of the lifting pin 112 passes through the stage 105 and the plate portion 108a of the temperature regulation jacket 108, so that a lower end of the shaft portion of the lifting pin 112 protrudes from the plate portion 108a of the temperature regulation jacket 108. On the other hand, in a state where the stage 105 is moved to the transfer position of the substrate W (not illustrated), the lower end of the lifting pin 112 is brought into contact with the abutter 113, and the head portion of the lifting pin 112 protrudes from the placement surface of the stage 105. With this configuration, the head portion of the lifting pin 112 supports the substrate W from the lower surface thereof and raises the substrate W from the placement surface of the stage 105.

The abutter 113 has a contact portion 113a that is brought into contact with the lifting pin 112 and a shaft portion 113b that extends downward from the contact portion 113a. The shaft portion 113b of the abutter 113 passes through the bottom of the main body container 101. A lower end of the abutter 113 is supported by a lifting mechanism 115 via a lifting plate 114 disposed below the main body container 101. A bellows 116 is provided between the bottom of the main body container 101 and the lifting plate 114 to maintain airtightness inside the main body container 101 even with a vertical movement of the lifting plate 114. The lifting mechanism 115 can move the abutter 113 vertically by raising and lowering the lifting plate 114. As the lower end of the lifting pin 112 is brought into contact with an upper surface of the abutter 113, an upper end of the lifting pin 112 can support the substrate W from the lower surface thereof.

An annular member 117 is disposed above the stage 105. In the state where the stage 105 is moved to the processing position of the substrate W (see FIG. 1), the annular member 117 is brought into contact with an outer peripheral portion of an upper surface of the substrate W, thereby pressing the substrate W onto the placement surface of the stage 105 by a weight of the annular member 117. On the other hand, in the state where the stage 105 is moved to the transfer position of the substrate W (not illustrated), the annular member 117 is engaged and locked by a locker (not illustrated) at a location above the loading/unloading port 101a, so as not to hinder the transfer of the substrate W by the transfer mechanism (not illustrated).

A heat transfer gas supply and exhauster 119 supplies a heat transfer gas, for example, He gas, to a backside space between a rear surface of the substrate W placed on the stage 105 and a front surface of the stage 105 via a pipe 119a.

A purge gas supply 120 supplies a purge gas between a lower surface of the annular member 117 and an upper surface of the stage 105 via a pipe 120a, a gap (not illustrated) formed between the support portion 105a of the stage 105 and the bore 108c of the temperature regulation jacket 108, a flow path (not illustrated) that is formed between the stage 105 and the heat insulation ring 107 and extends radially outward, and a vertical flow path (not illustrated) formed in an outer peripheral portion of the stage 105. With this configuration, the process gas is suppressed from entering a space between the lower surface of the annular member 117 and the upper surface of the stage 105.

A sidewall of the main body container 101 is provided with the loading/unloading port 101a for loading and unloading the substrate W and a gate valve 121 for opening and closing the loading/unloading port 101a.

An exhauster 122, which includes a vacuum pump and the like, is connected to a lower portion of the sidewall of the main body container 101 via an exhaust pipe 101b. An interior of the main body container 101 is exhausted by the exhauster 122, so that an interior of the processing chamber 101c is set and maintained to be a predetermined vacuum atmosphere (e.g., 1.33 Pa).

A controller 130 controls operations of the substrate processing apparatus 100 by

controlling the respective components such as the gas supply 104, heater 106, lifting mechanism 110, coolant unit 118, heat transfer gas supply and exhauster 119, purge gas supply 120, gate valve 121, and exhauster 122.

During the processing, the controller 130 supplies the process gas from the gas supply 104 to an upper space 101d of the processing chamber 101c via the supply pipe 102a and the gas introduction mechanism 103. After the processing, the gas flows from the upper space 101d to a lower space 101e via a flow path on a side of the upper surface of the annular member 117, and is exhausted by the exhauster 122 via the exhaust pipe 101b.

### <Surface Processing Method for Substrate>

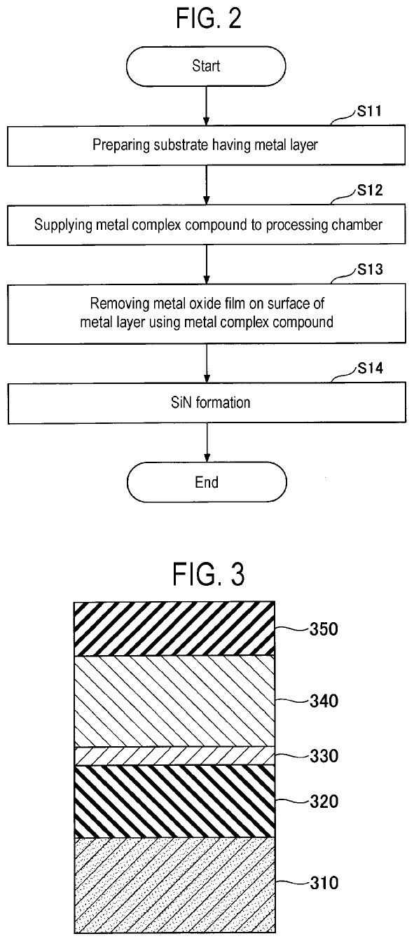

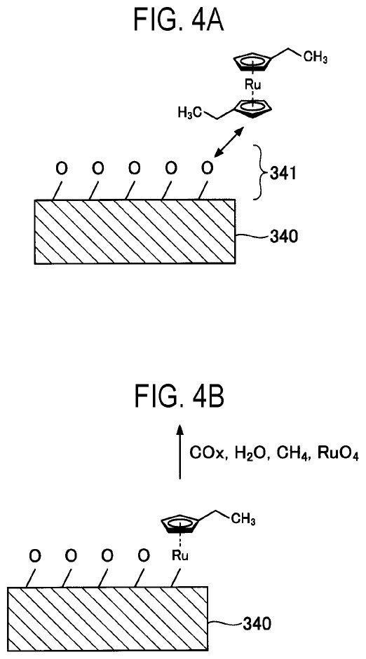

Next, an example of a surface processing method for the substrate W according to a first embodiment will be described with reference to FIGS. 2 and 3. FIG. 2 is a flowchart illustrating an example of a surface processing method for the substrate W according to the first embodiment. FIG. 3 is a cross-sectional schematic diagram illustrating an example of a structure of the substrate W.

In step S11, the substrate W having a metal layer 340 (see FIG. 3) is prepared. Specifically, the interior of the processing chamber 101c is set to be a predetermined vacuum atmosphere by the exhauster 122. The controller 130 controls the lifting mechanism 110 to locate the stage 105 at the transfer position, and then opens the gate valve 121. The substrate W is transferred into the main body container 101 from the loading/unloading port 101a by the transfer mechanism (not illustrated). The controller 130 controls the lifting mechanism 115 to transfer the substrate W to the lifting pins 112. Once the transfer mechanism has been retracted from the loading/unloading port 101a, the controller 130 closes the gate valve 121. The controller 130 controls the lifting mechanisms 110 and 115 to place the substrate W on the stage 105 and to move the stage 105 from the transfer position to the processing position (see FIG. 1). In addition, as the stage 105 is raised to the processing position, the annular member 117 is brought into contact with the outer peripheral portion of the upper surface of the substrate W, thereby pressing the substrate W onto the placement surface of the stage 105 by the weight of the annular member 117. In addition, the controller 130 controls the heater 106 and the coolant unit 118 to control the temperature of the substrate W placed on the stage 105. Further, the controller 130 controls the heat transfer gas supply and exhauster 119 to supply the heat transfer gas to the backside space between the rear surface of the substrate W placed on the stage 105 and the front surface of the stage 105. In addition, the controller 130 controls the purge gas supply 120 to supply the purge gas between the lower surface of the annular member 117 and the upper surface of the stage 105.

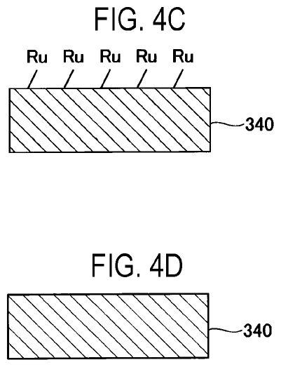

Here, the substrate W prepared in step S11 is formed by stacking a substrate 310 made of, for example, Si, an insulating layer 320 made of, for example, SiO₂, a barrier metal layer 330 made of, for example, TaN, and the metal layer 340 made of, for example, Ru, as illustrated in FIG. 3. In addition, a metal oxide film 341 (see FIG. 4A to be described later) is formed on a surface of the metal layer 340. In addition, a SiN film 350 on the metal layer 340 is formed in step S14 to be described later.

In addition, in the following description, the metal layer 340 is described as being made of Ru, but is not limited thereto. The metal layer 340 contains at least one selected from the group consisting of Ru, Rh, Pd, Os, Ir, Pt, Cu, Co, W, Ti, Ni, and Mo.

In step S12, a metal complex compound gas is supplied to the processing chamber 101c. Specifically, the controller 130 controls the gas supply 104 to supply the metal complex compound gas to the processing chamber 101c.

Here, a metal complex compound is a metal complex compound having a cyclopentadienyl ligand. In addition, particularly, the metal complex compound may be a complex compound containing a transition metal with a cyclopentadienyl ligand. In addition, more particularly, the metal complex compound may be a complex compound having a cyclopentadienyl ligand and containing at least one selected from the group consisting of Ru, Rh, Pd, Os, Ir, Pt, Cu, Co, W, Ti, Ni, and Mo. In the following description, the metal complex compound having a cyclopentadienyl ligand is described as being bis(ethylcyclopentadienyl)ruthenium(II): Ru(EtCp)₂. The gas supply 104 heats Ru (EtCp)₂ in a liquid phase to supply vaporized Ru(EtCp)₂ gas along with a carrier gas. The temperature of the substrate W at this time may be a temperature at which thermal decomposition of Ru(EtCp)₂ and formation of a Ru film are less likely to occur, for example, less than 500 degrees C. The gas supply 104 may also supply an oxidizing gas such as oxygen (O₂) gas, in addition to the Ru(EtCp)₂ gas and the carrier gas. In addition, the gas supply 104 may supply a dilution gas to dilute the Ru(EtCp)₂ gas, in addition to the Ru(EtCp)₂ gas and the carrier gas. For example, an inert gas such as argon (Ar) gas may be used as the carrier gas and the dilution gas.

In step S13, the metal oxide film 341 on the surface of the metal layer 340 is removed (reduced) by using the metal complex compound.

FIGS. 4A to 4D illustrate an example of a reaction model in which the metal oxide film 341 is removed by using the metal complex compound.

As illustrated in FIG. 4A, the metal oxide film 341 is formed on the surface of the metal layer 340 of the substrate W prepared in step S11. In step S12, Ru(EtCp)₂, which is an example of a metal complex compound having a cyclopentadienyl ligand, is supplied into the processing chamber 101c.

The cyclopentadienyl ligand (Cp) of Ru(EtCp)₂ reacts with the oxygen (—O) or —OH terminal (not illustrated) of the metal oxide film 341, causing oxygen to be released from the metal oxide film 341 formed on the surface of the metal layer 340, and causing Ru to be adsorbed by a substitution reaction, as illustrated in FIG. 4B. In addition, COₓ, H₂O, CH₄, and RuO₄ are generated as reaction by-products, and are exhausted to the outside of the processing chamber 101c by the exhauster 122. When the temperature of the substrate W is less than 150 degrees C., the oxidizing gas such as oxygen (O₂) gas may be supply simultaneously in order to slightly facilitate decomposition of Ru(EtCp)₂. When the temperature of the substrate W is 150 degrees C. or higher, the formation of a Ru film proceeds, and therefore, it is not desirable to supply the oxidizing gas such as oxygen (O₂) gas simultaneously.

Thereafter, the surface of the deoxygenated metal layer 340 becomes a state where Ru is adsorbed as illustrated in FIG. 4C, or a state where Ru has re-desorbed as illustrated in FIG. 4D. With this configuration, the metal oxide film 341 on the metal layer 340 is removed (reduced) (step S13).

Returning to FIG. 2, in step S14, the SiN film 350 (see FIG. 3) is formed on the metal layer 340 from which the metal oxide film 341 has been removed. Here, the process of removing the metal oxide film 341 (steps S11 to S13) and the process of forming the SiN film 350 (step S14) may be performed in the processing chamber 101c of the same substrate processing apparatus 100. Alternatively, the substrate processing apparatus 100 that performs the process of removing the metal oxide film 341 (steps S11 to S13) may transfer the substrate to another substrate processing apparatus (not illustrated) without breaking a vacuum, so that the process of forming the SiN film 350 (step S14) may be performed in the another substrate processing apparatus.

Next, the surface processing method for the substrate W according to the first embodiment will be further described in comparison with reference examples.

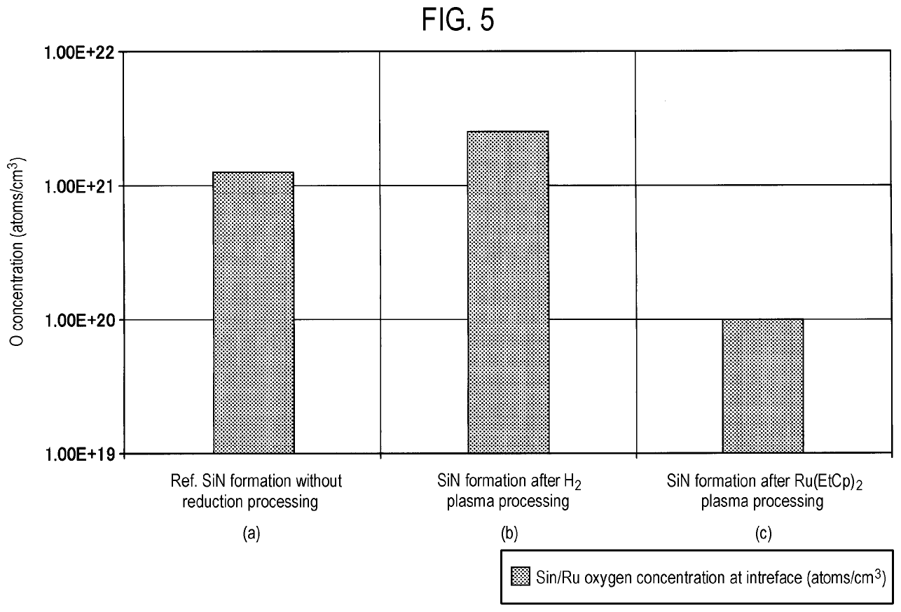

FIG. 5 is an example of a graph illustrating oxygen concentrations at an interface between the SiN film 350 and the metal layer 340 in the surface processing method of the first embodiment and surface processing methods of reference examples. Here, the oxygen concentration was measured by secondary ion mass spectrometry (SIMS), and the results show a peak value of the oxygen concentration at the interface between the SiN film 350 and the metal layer 340.

(a) illustrates a result of a surface processing method of a first reference example. In the surface processing method of the first reference example, the SiN film 350 was formed on the metal layer 340, which is made of Ru and has the metal oxide film 341 formed on the surface thereof, without a reduction processing.

(b) illustrates a result of a surface processing method of a second reference example. In the surface processing method of the second reference example, after processing the metal layer 340, which is made of Ru and has the metal oxide film 341 formed on the surface thereof, by using H₂ plasma at 550 degrees C., the SiN film 350 was formed on the metal layer 340.

(c) illustrates a result of the surface processing method of the first embodiment (see FIG. 2). In the surface processing method of the first embodiment, after processing the metal layer 340, which is made of Ru and has the metal oxide film 341 formed on the surface thereof, by flowing only Ru(EtCp)₂ gas at 275 degrees C. and 1 Torr for five minutes, the SiN film 350 was formed on the metal layer 340.

As illustrated in the comparison results between (c) of FIG. 5 and (a) of FIG. 5 and between (c) of FIG. 5 and (b) of FIG. 5, according to the surface processing method of the first embodiment (see FIG. 2), reduction in oxygen concentration at the interface between the SiN film 350 and the metal layer 340 could be confirmed. In other words, it could be confirmed that the process illustrated in steps S11 to S13 in FIG. 2 results in the removal (reduction) of the metal oxide film 341 on the surface of the metal layer 340.

As described above, the surface processing method according to the first embodiment can remove (reduce) the metal oxide film 341 on the surface of the metal layer 340.

In addition, the surface processing method according to the first embodiment can perform the reduction processing without using plasma and can lower a process temperature range, as compared to the reduction processing using plasma. Thus, it is possible to suppress any effects on the structure around the metal layer 340 during the reduction processing.

In addition, as illustrated in FIGS. 4A to 4D, in the surface processing method according to the first embodiment, the cyclopentadienyl ligand (Cp) of the metal complex compound reacts with oxygen in the metal oxide film 341, leading to the release of oxygen from the metal oxide film 341 on the surface of the metal layer 340, and consequently, leading to the removal (reduction) of the metal oxide film 341. On the other hand, the cyclopentadienyl ligand (Cp) of the metal complex compound does not react with stable oxides or nitrides such as SiO, SiN, or AlO, and neither reduction nor Ru adsorption occurs. Thus, the surface processing method according to the first embodiment can selectively reduce the metal oxide film 341 on the metal layer 340.

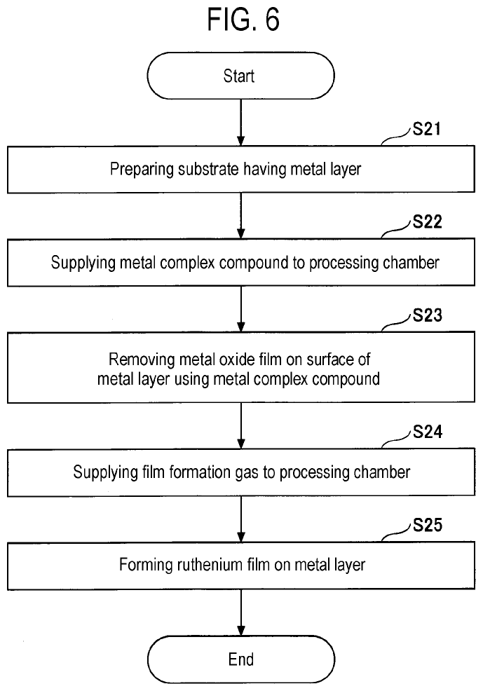

Next, an example of a surface processing method for the substrate W according to a second embodiment will be described with reference to FIG. 6. FIG. 6 is a flowchart illustrating an example of the surface processing method for the substrate W according to the second embodiment.

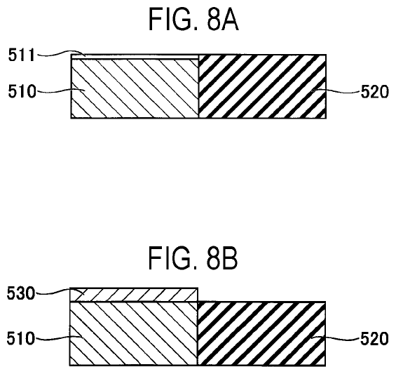

In step S21, the substrate W having a metal layer 510 (see FIG. 8A to be described later) is prepared. In addition, the process of step S21 is the same as that of step S11 (see FIG. 2), and a redundant description thereof is omitted. In addition, in the following description, the metal layer 510 is described as being made of Ru, but is not limited thereto. The metal layer 510 contains at least one selected from the group consisting of Ru, Rh, Pd, Os, Ir, Pt, Cu, Co, W, Ti, Ni, and Mo.

In step S22, a metal complex compound gas is supplied to the processing chamber 101c. In addition, the process of step S22 is the same as that of step S12 (see FIG. 2), and a redundant description thereof is omitted. Here, a metal complex compound is a metal complex compound having a cyclopentadienyl ligand. In addition, particularly, the metal complex compound may be a complex compound containing a transition metal with a cyclopentadienyl ligand. In addition, more particularly, the metal complex compound may be a complex compound having a cyclopentadienyl ligand and containing at least one selected from the group consisting of Ru, Rh, Pd, Os, Ir, Pt, Cu, Co, W, Ti, Ni, and Mo. In the following description, the metal complex compound having a cyclopentadienyl ligand is described as being Ru(EtCp)₂.

In step S23, a metal oxide film 511 (see FIG. 8A to be described later) on a surface of the metal layer 510 is removed (reduced) by using the metal complex compound. In addition, the process of step S23 is the same as that of step S13 (see FIG. 2), and a redundant description thereof is omitted.

In step S24, a film formation gas for forming a metal film 530 (see FIG. 8B to be described later) is supplied to the processing chamber 101c. Specifically, the controller 130 controls the gas supply 104 to supply the film formation gas to the processing chamber 101c.

Here, when forming a ruthenium film as the metal film 530, for example, Ru(EtCp)₂ gas, which is the metal complex compound gas used in step S22, and O₂ gas may be used as the film formation gas. When forming the ruthenium film using the Ru(EtCp)₂ gas and the O₂ gas, the temperature of the substrate W is controlled to be 150 degrees C. or higher. In addition, when forming the ruthenium film using only the Ru(EtCp)₂ gas, the temperature of the substrate W is controlled to be 500 degrees C. or higher.

The gas supply 104 may alternately repeat a process of supplying the Ru(EtCp)₂ gas and a process of supplying the O₂ gas to form the ruthenium film by an atomic layer deposition (ALD) method. In the process of supplying the Ru(EtCp)₂ gas, the gas supply 104 heats Ru (EtCp)₂ in a liquid phase to supply vaporized Ru (EtCp)₂ gas along with a carrier gas to the processing chamber 101c. In addition, the gas supply 104 may supply a dilution gas to dilute the Ru(EtCp)₂ gas to the processing chamber 101c, in addition to the Ru(EtCp)₂ gas and the carrier gas. For example, an inert gas such as argon (Ar) gas may be used as the carrier gas and the dilution gas. In the process of supplying the O₂ gas, the gas supply 104 supplies the O₂ gas to the processing chamber 101c. Without being limited to the O₂ gas, an oxidizing gas such as O₃ gas may be supplied. In addition, the gas supply 104 may supply a dilution gas to dilute the O₂ gas to the processing chamber 101c, in addition to the O₂ gas. For example, an inert gas such as argon (Ar) gas may be used as the dilution gas. In addition, after the process of supplying the Ru(EtCp)₂ gas and the process of supplying the O₂ gas, a process of purging an excess gas or the like in the processing chamber 101c may be performed. In the purging process, the gas supply 104 supplies a purge gas to the processing chamber 101c. For example, an inert gas such as argon (Ar) gas may be used as the purge gas.

In addition, the gas supply 104 may form the ruthenium film by a chemical vapor deposition (CVD) method by simultaneously supplying the Ru (EtCp)₂ gas and the O₂ gas. The gas supply 104 heats Ru (EtCp)₂ in a liquid phase to supply vaporized Ru (EtCp)₂ gas, O₂ gas, a carrier gas, and a dilution gas to the processing chamber 101c. Without being limited to the O₂ gas, an oxidizing gas such as O₃ gas may be supplied. For example, an inert gas such as argon (Ar) gas may be used as the carrier gas and the dilution gas.

In addition, when forming the ruthenium film as the metal film 530, a gas different from the metal complex compound gas used in step S22 may be used. For example, Ru₃(CO)₁₂ gas and CO gas may be used as the film formation gas.

The gas supply 104 simultaneously supplies the Ru₃(CO) 12 gas and the CO gas to the processing chamber 101c. The Ru₃(CO)₁₂ gas is a ruthenium-containing gas. The CO gas is a gas that inhibits decomposition of Ru₃(CO)₁₂. The ruthenium film is formed on the substrate W by decomposition of Ru₃(CO)₁₂ on the surface of the substrate W. The temperature of the substrate W may range from 50 degrees C. to 300 degrees C. Ru₃(CO)₁₂ has a higher film formation rate compared to Ru(EtCp)₂. Thus, film formation can be performed with high productivity, for example, in a case where a low temperature processing is required. In addition, removal of the metal oxide film and formation of the metal film may be performed at an isothermal condition.

In step S25, the metal film 530 (see FIG. 8B to be described later) is formed on the metal layer 510 from which the metal oxide film 511 has been removed. In addition, the case where the metal layer 510 is made of Ru and the metal film 530 to be formed is the same ruthenium film as the metal layer has been described, but the present disclosure is not limited thereto. The metal film 530 contains at least one selected from the group consisting of Ru, Rh, Pd, Os, Ir, Pt, Cu, Co, W, Ti, Ni, and Mo. The metal layer 510 and the metal film 530 may be of any combination.

In addition, the process of removing the metal oxide film 511 (steps S21 to S23) and the process of forming the metal film 530 (steps S24 and S25) may be performed consecutively in the processing chamber 101c of the same substrate processing apparatus 100 without breaking a vacuum. Alternatively, the substrate processing apparatus 100 that performs the process of removing the metal oxide film 511 (steps S21 to S23) may transfer the substrate to another substrate processing apparatus (not illustrated) without breaking a vacuum, so that the process of forming the metal film 530 (steps S24 and S25) may be performed in the another substrate processing apparatus.

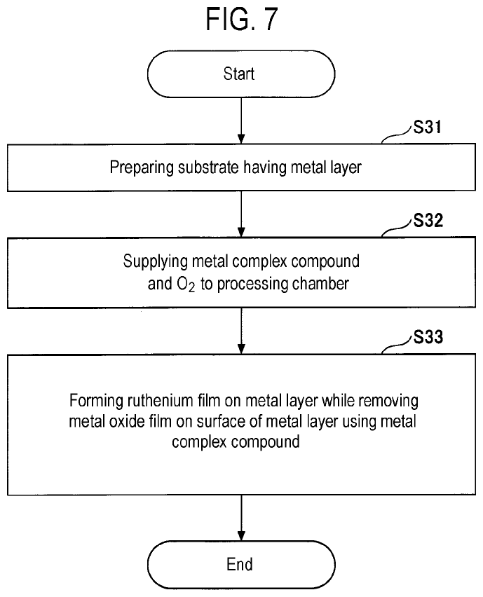

Next, an example of a surface processing method for the substrate W according to a third embodiment will be described with reference to FIG. 7. FIG. 7 is a flowchart illustrating an example of the surface processing method for the substrate W according to the third embodiment.

In step S31, the substrate W having the metal layer 510 (see FIG. 8A to be described later) is prepared. In addition, the process of step S31 is the same as that of step S11 (see FIG. 2), and a redundant description thereof is omitted. In addition, in the following description, the metal layer 510 is described as being made of Ru, but is not limited thereto. The metal layer 510 contains at least one selected from the group consisting of Ru, Rh, Pd, Os, Ir, Pt, Cu, Co, W, Ti, Ni, and Mo.

In step S32, a metal complex compound gas and O₂ gas are supplied simultaneously to the processing chamber 101c. Here, a metal complex compound is a metal complex compound having a cyclopentadienyl ligand. In addition, particularly, the metal complex compound may be a complex compound containing a transition metal with a cyclopentadienyl ligand. In addition, more particularly, the metal complex compound may be a complex compound having a cyclopentadienyl ligand and containing at least one selected from the group consisting of Ru, Rh, Pd, Os, Ir, Pt, Cu, Co, W, Ti, Ni, and Mo. In the following description, the metal complex compound having a cyclopentadienyl ligand is described as being Ru(EtCp)₂. The gas supply 104 heats Ru (EtCp)₂ in a liquid phase to supply vaporized Ru (EtCp)₂ gas, O₂ gas, a carrier gas, and a dilution gas to the processing chamber 101c. Without being limited to the O₂ gas, an oxidizing gas such as O₃ gas may be supplied. For example, an inert gas such as argon (Ar) gas may be used as the carrier gas and the dilution gas. The temperature of the substrate W is controlled to be 150 degrees C. or higher.

In step S33, the metal oxide film 511 (see FIG. 8B to be described later) on the surface of the metal layer 510 is removed (reduced) by using the metal complex compound, and the metal film 530 (see FIG. 8B to be described later) is formed on the metal layer 510. In addition, when supplying the Ru(EtCp)₂ gas, the carrier gas, and the dilution gas to the processing chamber 101c (without supplying the O₂ gas), the temperature of the substrate W is controlled to be 500 degrees C. or higher. In addition, although the case where the metal layer 510 is made of Ru and the metal film 530 to be formed is the same ruthenium film as the metal layer has been described, but the present disclosure is not limited thereto. The metal film 530 contains at least one selected from the group consisting of Ru, Rh, Pd, Os, Ir, Pt, Cu, Co, W, Ti, Ni, and Mo. The metal layer 510 and the metal film 530 may be of any combination.

FIGS. 8A and 8B are cross-sectional schematic diagrams illustrating an example of an upper structure of the substrate W.

The surface processing method for the substrate W according to the second embodiment will be described with reference to FIGS. 6, 8A, and 8B.

As illustrated in FIG. 8A, the substrate W prepared in step S21 has the metal layer 510 made of, for example, Ru and an insulating layer 520 formed on the substrate W. In addition, the metal oxide film 511 is formed on the surface of the metal layer 510. In addition, the insulating layer 520 is made of, for example, stable oxides or nitrides such as SiO, SiN, or AlO, and is used as, for example, an interlayer insulation film (low-k film).

In step S22, Ru(EtCp)₂, which is an example of a metal complex compound having a cyclopentadienyl ligand, is supplied into the processing chamber 101c. The cyclopentadienyl ligand (Cp) of Ru(EtCp)₂ reacts with the oxygen (—O) or —OH terminal (not illustrated) of the metal oxide film 511, causing oxygen to be released from the metal oxide film 511 on the surface of the metal layer 510, and causing Ru to be adsorbed by a substitution reaction. Thereafter, the surface of the deoxygenated metal layer 510 becomes a state where Ru has adsorbed or a state where Ru has re-desorbed. Thus, the metal oxide film 511 on the metal layer 510 is removed (reduced) (step S23).

In addition, the cyclopentadienyl ligand (Cp) of the metal complex compound does not react with the insulating layer 520 made of stable oxides or nitrides such as SiO, SiN, or AlO, and neither reduction nor Ru adsorption occurs. Thus, it is possible to suppress damage to the insulating layer 520 and selectively reduce the metal oxide film 511 on the metal layer 510.

In step S24, Ru(EtCp)₂ and O₂ are supplied into the processing chamber 101c. Thus, as illustrated in FIG. 8B, the metal film 530 may be selectively formed on the metal layer 510 (step S25).

The surface processing method for the substrate W according to the third embodiment will be described with reference to FIGS. 7, 8A, and 8B.

As illustrated in FIG. 8A, the substrate W prepared in step S31 has the metal layer 510 made of, for example, Ru and the insulating layer 520 formed on the substrate W. In addition, the metal oxide film 511 is formed on the surface of the metal layer 510. In addition, the insulating layer 520 is made of, for example, stable oxides or nitrides such as SiO, SiN, or AlO, and is used as, for example, an interlayer insulating film (low-k film).

In step S32, Ru(EtCp)₂ and O₂ are supplied into the processing chamber 101c. Thus, the metal oxide film 511 on the metal layer 510 may be removed (reduced), and as illustrated in FIG. 8B, the metal film 530 may be selectively formed on the metal layer 510 (step S33).

As described above, the surface processing methods according to the second and third embodiments can remove (reduce) the metal oxide film 511 on the surface of the metal layer 510 and can selectively form the metal film 530 on the surface of the metal layer 510.

In addition, the surface processing methods according to the second and third embodiments can perform the reduction processing without using plasma and can lower a process temperature range, as compared to the reduction processing using plasma. Thus, it is possible to suppress any effects on the structure (e.g., the insulating layer 520 used as an interlayer insulating film) around the metal layer 340 during the reduction processing.

In addition, in the surface processing method according to the second embodiment, for example, Ru₃(CO) 12 gas and CO gas may be used in formation of the metal film 530. Thus, since the metal film 530 can be formed without using oxygen (O), oxygen (O) of the metal film 530 can be decreased.

Although the surface processing method of the present embodiment by the substrate processing apparatus 100 has been described above, the present disclosure is not limited to the above-described embodiments and the like, and various modifications and improvements can be made within the scope of the gist of the present disclosure described in the claims.

The processes have been described as being performed on the substrate W in a single-wafer type processing apparatus, but are not limited thereto. The processes according to the present embodiments may also be applied to a batch type or semi-batch type processing apparatus that process a plurality of substrates W simultaneously.

In addition, the present application claims the priority based on Japanese Patent Application No. 2021-68978 filed on Apr. 15, 2021, and the contents of this Japanese patent application are fully incorporated herein by reference.

### EXPLANATION OF REFERENCE NUMERALS

W: substrate, 100: substrate processing apparatus, 101: main body container, 101c: processing chamber, 103: gas introduction mechanism, 104: gas supply, 105: stage, 130: controller, 340: metal layer, 341: metal oxide film, 350: SiN film, 510: metal layer, 511: metal oxide film, 520: insulating layer, 530: metal film.

What is claimed is:

1. A surface processing method for a substrate having a metal layer, the method comprising:
supplying a metal complex compound having a cyclopentadienyl ligand to a processing chamber; and
removing a metal oxide film on a surface of the metal layer using the metal complex compound.

2. The surface processing method of claim 1, wherein the metal complex compound is a complex compound containing a transition metal with the cyclopentadienyl ligand.

3. The surface processing method of claim 2, wherein the metal complex compound is a complex compound having the cyclopentadienyl ligand and containing at least one selected from the group consisting of Ru, Rh, Pd, Os, Ir, Pt, Cu, Co, W, Ti, Ni, and Mo.

4. The surface processing method of claim 1, wherein the metal layer contains at least one selected from the group consisting of Ru, Rh, Pd, Os, Ir, Pt, Cu, Co, W, Ti, Ni, and Mo.

5. The surface processing method of claim 1, further comprising forming a metal film on the metal layer after the removing the metal oxide film.

6. The surface processing method of claim 5, wherein the metal film contains at least one selected from the group consisting of Ru, Rh, Pd, Os, Ir, Pt, Cu, Co, W, Ti, Ni, and Mo.

7. The surface processing method of claim 5, wherein the metal film is a ruthenium film.

8. The surface processing method of claim 7, wherein the metal complex compound is Ru (EtCP)₂, and
wherein the forming the metal film includes supplying Ru(EtCP)₂ and O₂ to the processing chamber.

9. The surface processing method of claim 5, wherein the removing the metal oxide film and the forming the metal film are performed consecutively without breaking a vacuum.

10. A substrate processing apparatus comprising:
a processing container configured to accommodate a substrate having a metal layer;
a supply configured to supply a metal complex compound having a cyclopentadienyl ligand to the processing container; and
a controller,
wherein the controller supplies the metal complex compound to the processing container to remove a metal oxide film on a surface of the metal layer.
